(19) United States
(12) Patent Application Publication
(10) Pub. No.: US 2025/0130557 A1
(43) Pub. Date: Apr. 24, 2025

(54) SYSTEM AND METHOD FOR CONTROLLING A CONVEYOR IN VIRTUAL ENVIRONMENT

(71) Applicant: HYUNDAI AUTOEVER CORP., Seoul (KR)

(72) Inventors: Jae Min Ko, Seoul (KR); Yoon Ji Lee, Seoul (KR); Ki Ho Kim, Seoul (KR); Yun Ho Yang, Seoul (KR); Joong Hui Kim, Seoul (KR); Sae Hyeon Kim, Seoul (KR); Hee Jin Ju, Seoul (KR); Hye Yun Jung, Seoul (KR); Jeong Woo Woo, Seoul (KR)

(73) Assignee: HYUNDAI AUTOEVER CORP., Seoul (KR)

(21) Appl. No.: 18/918,923

(22) Filed: Oct. 17, 2024

(30) Foreign Application Priority Data
Oct. 18, 2023 (KR) 10-2023-0139557

(51) Int. Cl. G05B 19/418

(52) U.S. Cl. CPC G05B 19/41865; G05B 2219/45054

(57) ABSTRACT

A system for controlling a conveyor in a virtual environment includes a twin model module comprising control logic and configured to virtualize a control system for conveyors installed in a factory. The system also includes a digital factory module configured to virtualize the conveyors installed in the factory and create a virtual factory model controlled by the twin model module. A virtualized conveyor includes multiple paths formed by segmenting the conveyor based on joints. The twin model module is configured to control transportation routes of products based on the joints.

### CROSS REFERENCE TO RELATED APPLICATION

This application claims the benefit of and priority to Korea Patent Application No. 10-2023-0139557, filed on Oct. 18, 2023, the entire disclosure of which is hereby incorporated herein by reference in its entirety.

### FIELD OF TECHNOLOGY

The present disclosure relates to a system and a method for controlling a conveyor in a virtual environment.

### BACKGROUND

Digital twin technology involves creating a virtual representation of a facility or factory in a virtual space, where the virtual representation is the same as or similar to an actual facility or factory, in order to conduct various simulations for testing purposes. This technology has been introduced and is being utilized across different fields including manufacturing, aviation, construction, healthcare, energy, national defense, city planning, etc.

The digital twin technology enables monitoring of the state of a facility or a system in a virtual space to identify timings for maintenance or repair. The digital twin technology also facilitates testing of various situations that may occur during operation, allowing for proactive prevention of unexpected accidents and reduction of accident risks. Furthermore, this technology may enhance productivity, optimize facilities, and significantly reduce costs and time associated with manufacturing trial products.

Such a digital twin system may be implemented either on a personal computer or on a server. Users may utilize a personal computer or access the relevant server to simulate a virtual factory for testing an actual factory.

A virtual factory may include conveyors that serve to transport products as a basic element composing a warehouse. Through the conveyors, transportation flows of products may be controlled in a virtual factory environment, and virtualizing the conveyors allows effective simulations for a virtual factory.

The discussions in this section are intended merely to provide background information and do not constitute an admission of prior art.

### SUMMARY

Embodiments of the present disclosure provide a system and a method for controlling conveyors in a virtual environment, capable of effectively controlling virtual conveyors in a virtual factory by segmenting a virtualized conveyor into multiple paths based on joints and controlling a transportation route of products.

Other embodiments of the present disclosure provide a system and a method for controlling conveyors in a virtual environment in which a control system of a factory and a physical factory may be virtualized respectively in separate modules.

Technological tasks of the present disclosure are not limited to those mentioned above. Other technological tasks, that are not mentioned above, should be more clearly understood by a person having ordinary skill in the art to which the present disclosure pertains from the following descriptions.

According to an aspect of the present disclosure, a system for controlling conveyors in a virtual environment is provided. The system includes a twin model module comprising control logic and virtualizing a control system for conveyors installed in a factory. The system also includes a digital factory module virtualizing the conveyors installed in the factory and creating a virtual factory model controlled by the twin model module. A virtualized conveyor includes multiple paths formed by segmenting the conveyor based on joints. The twin model module may control transportation routes of products based on joints.

In an embodiment, when a product is being transported through the multiple paths included in the conveyor, the twin model module may verify whether the distance of the product to a preceding product is within a predetermined range and, when the distance is within the predetermined range, control the product in transportation to stop by the control logic.

In an embodiment, the predetermined range may correspond to a safety distance set for preventing collision with the preceding product.

In an embodiment, the multiple paths may include at least one straight path and at least one turning path.

In an embodiment, the twin model module may set at least one of a length, an angle of gradient, or a moving speed for each straight path.

In an embodiment, the twin model module may set at least one of a turning section, a turning angle, or a moving speed for each turning path.

In an embodiment, the twin model module may set transportation routes of products that are transported through the conveyor based on combination of the multiple paths.

In an embodiment, a direction changing unit for changing directions may be disposed in each joint.

In an embodiment, the direction changing unit may include a bar code or a bar code reader.

In an embodiment, the bar code may include information on whether to change directions.

In an embodiment, when it is verified that the product in transportation is not a target for direction change as a result of bar code scanning, the twin model module may control the product in transportation to go straight by the control logic.

In an embodiment, when it is verified that the number of products on an entrance section of the conveyor is equal to or higher than a predetermined number as a result of bar code scanning, the twin model module may control the product in transportation to go straight by the control logic.

In an embodiment, when it is verified that it is not the turn for the product to enter as a result of bar code scanning, the twin model module may control the product in transportation to go straight by the control logic.

In an embodiment, when it is verified that the product in transportation is a target for direction change as a result of bar code scanning, the twin model module may control the product in transportation to change its direction by the control logic.

In an embodiment, the system for controlling conveyors in a virtual environment may include multiple twin model modules, and may further include a simulator module to control the multiple twin model modules.

In an embodiment, the multiple twin model modules are executed on at least one graphics processing unit (GPU) server, and when a first twin model module from among the multiple twin model modules is executed, the simulator module may assign resources for executing the first twin model module in the at least one GPU server.

In an embodiment, the simulator module may set up conditions of the control logic for each twin model module to control a virtual factory.

In an embodiment, the simulator module may create webpages to set up the conditions of the control logic and set up the conditions of the control logic using set values inputted through the webpages.

In an embodiment, each twin model module and the digital factory module may communicate with each other using any one of interfaces, including a remote procedure call (RPC), a RestAPI, a Socket, a Kafka, and a Message Queue (MQ).

In an embodiment, the factory may include production factories or logistics factories.

In an embodiment, the digital factory module may report a result corresponding to a control command to a twin model module connected with this digital factory module.

In an embodiment, the product may be transported using a product box.

According to another aspect of the present disclosure, a method for controlling a conveyor in a virtual environment is provided. The method includes registering and initializing, by a simulator module, a model for a digital factory including a virtualized conveyor, that is a virtual representation of a conveyor installed in an actual factory. The method also includes requesting, by the simulator module, the start of a simulation from a twin model module, that is a virtual representation of a control system for the factory. The method additionally includes generating, by the twin model module, control logic for the digital factory. The method further includes transferring, by the twin model module, a command generated based on the control logic to a digital factory module. The method also includes processing, by the digital factory module, an operation corresponding to the command received from the twin model module to conduct a simulation. The virtualized conveyor is segmented into multiple paths based on joints. The twin model module may control transportation routes of products based on the joints.

In an embodiment, when a product is being transported through the multiple paths included in the conveyor, the twin model module may verify whether the distance of the product to a preceding product is within a predetermined range and, when the distance is within the predetermined range, control the product in transportation to stop by the control logic.

In an embodiment, the predetermined range may correspond to a safety distance set for preventing collision with the preceding product.

In an embodiment, the multiple paths may include at least one straight path and at least one turning path.

In an embodiment, the twin model module may set at least one of a length, an angle of gradient, or a moving speed for each straight path.

In an embodiment, the twin model module may set at least one of a turning section, a turning angle, or a moving speed for each turning path.

In an embodiment, the twin model module may set transportation routes of products that are transported through the conveyor based on combination of the multiple paths.

In an embodiment, a direction changing unit for changing directions may be disposed in each joint.

In an embodiment, the direction changing unit may include a bar code or a bar code reader.

In an embodiment, the bar code may include information on whether to change directions.

In an embodiment, when it is verified that the product in transportation is not a target for direction change as a result of bar code scanning, the twin model module may control the product in transportation to go straight by the control logic.

In an embodiment, when it is verified that the number of products on an entrance section of the conveyor is equal to or higher than a predetermined number as a result of bar code scanning, the twin model module may control the product in transportation to go straight by the control logic.

In an embodiment, when it is verified that it is not the turn for the product to enter as a result of bar code scanning, the twin model module may control the product in transportation to go straight by the control logic.

In an embodiment, when it is verified that the product in transportation is a target for direction change as a result of bar code scanning, the twin model module may control the product in transportation to change its direction by the control logic.

In an embodiment, the factory may include production factories or logistics factories.

In an embodiment, the digital factory module may report a result corresponding to a control command to a twin model module connected with this digital factory module.

In an embodiment, the product may be transported using a product box.

As described above, embodiments of the present disclosure enable effective controls for virtualized conveyors in a virtualized factory by segmenting a virtualized conveyor into multiple paths based on joints to control a transportation route of products.

Additionally, embodiments of the present disclosure also enable various combinations of control systems and factories for conducting simulations by virtualizing each of control systems of factories and each of physical factories to be separate modules.

In addition to the effects described above, various other effects directly or indirectly understood from the present disclosure may be provided.

### BRIEF DESCRIPTION OF THE DRAWINGS

In order that the disclosure may be well understood, there are now described various forms thereof, given by way of example, reference being made to the accompanying drawings, in which:

FIG. 1 is a diagram illustrating a concept of a comparison between a virtual space and an actual space according to an embodiment of the present disclosure;

FIG. 2 is a flow diagram illustrating a control process of a digital twin system according to an embodiment of the present disclosure;

FIG. 3 is a block diagram illustrating a digital twin system according to an embodiment of the present disclosure;

FIG. 4 is a block diagram illustrating a digital twin system according to an embodiment of the present disclosure;

FIG. 5 is a diagram illustrating combinations of twin models and digital factories according to an embodiment of the present disclosure;

FIG. 6 is a diagram illustrating a process for a simulation of a factory according to an embodiment of the present disclosure;

FIG. 7 is a diagram illustrating a concept of a simulation of a factory according to an embodiment of the present disclosure;

FIG. 8A is a diagram illustrating a concept of a simulation of a factory using an emulator according to an embodiment of the present disclosure;

FIG. 8B is a diagram illustrating a concept of a simulation of a factory using a twin model according to an embodiment of the present disclosure;

FIG. 9 is a diagram illustrating operations or steps of editing and managing configurations for each model according to an embodiment of the present disclosure;

FIG. 10 is a diagram illustrating set values for configurations for each model according to an embodiment of the present disclosure;

FIG. 11 is a flow diagram illustrating operations or steps of editing and managing configurations for each model according to an embodiment of the present disclosure;

FIG. 12 is a diagram illustrating a structure for generating a set of configurations according to an embodiment of the present disclosure;

FIG. 13 is a diagram illustrating editing of sets of configurations according to an embodiment of the present disclosure;

FIG. 14 is a diagram illustrating a flow of processing data according to an embodiment of the present disclosure;

FIG. 15 is a diagram illustrating a method of processing data according to an embodiment of the present disclosure;

FIG. 16 is a diagram illustrating a method of generating indexes of a simulation result according to an embodiment of the present disclosure;

FIGS. 17A and 17B are diagrams illustrating a system for controlling conveyors in a virtual environment according to an embodiment of the present disclosure;

FIG. 18 is a flow diagram illustrating a control process of a conveyor according to an embodiment of the present disclosure;

FIG. 19 is a diagram illustrating program logic for controlling a conveyor in a virtual environment according to an embodiment of the present disclosure;

FIG. 20 is a flow diagram illustrating a control process of a conveyor according to an embodiment of the present disclosure;

FIG. 21 is a flow diagram illustrating a control process of a conveyor according to an embodiment of the present disclosure;

FIG. 22 is a flow diagram illustrating a control process of a conveyor according to an embodiment of the present disclosure;

FIG. 23 is a flow diagram illustrating a control process of a conveyor according to an embodiment of the present disclosure; and

FIG. 24 is a configuration diagram of hardware of a computing device according to some embodiments of the present disclosure.

### DETAILED DESCRIPTION

Hereinafter, embodiments of the present disclosure are described in detail with reference to the accompanying drawings. Advantages and characteristics of the present disclosure and methods to achieve them should be more clearly understood by referring to the accompanying drawings and the below described embodiments.

However, the present disclosure is not limited to the below disclosed embodiments, but may be implemented in various types different from each other. The embodiments are provided only for completing the present disclosure and for completely teaching the scope of the present disclosure to a person having ordinary skill in the art to which the present disclosure pertains. The present disclosure is defined only by the scope of the claims and their equivalents.

In describing the present disclosure, a detailed description of a well-known configuration or function related the present disclosure has been omitted where it was determined that the detailed description would unnecessarily obscure the gist of the present disclosure.

When a component, device, module, element, or the like of the present disclosure is described as having a purpose or performing an operation, function, or the like, the component, device, or element should be considered herein as being “configured to” meet that purpose or perform that operation or function.

Hereinafter, embodiments of the present disclosure are described in detail with reference to the accompanying drawings.

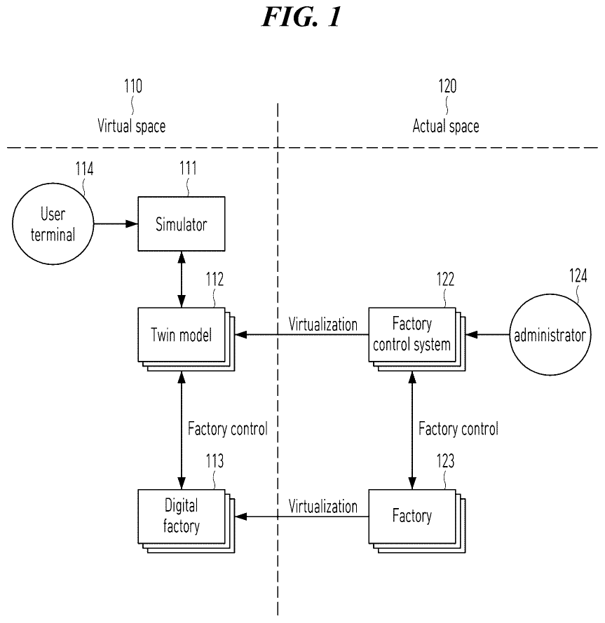

FIG. 1 is a diagram illustrating a concept of a comparison between a virtual space and an actual space according to an embodiment of the present disclosure.

Referring to FIG. 1, a digital twin system may be implemented by conducting simulations of virtual facilities or virtual factories, that are the same as or similar to actual facilities in an actual space 120, in a virtual space 110.

According to an embodiment, a factory 123 in the actual space may be controlled by a factory control system 122. An administrator 124 may set up control logic (or business logic) or input a control command through an input means of the factory control system 122. The factory control system 122 may generate commands for respective operations or steps according to the set control logic to control respective parts of the factory 123. For example, the factory control system 122 may cause transport of products or control movements of robots in accordance with certain control logic. In embodiments described below, the factory 123 may encompass production factories or logistics factories. However, the present disclosure is not limited thereto. For example, all the physical facilities that may be controlled by control logic may be included in the factories of the present disclosure.

According to an embodiment, the factory 123 in the actual space 120 may be virtualized to be a digital factory 113. The digital factory 113 may include a software and/or hardware module to virtualize the factory 123 in the actual space 120 for conducting simulations through a computer or server. Accordingly, the digital factory 113 may be referred to as a digital factory module. However, the present disclosure is not limited to this term.

According to an embodiment, the factory control system 122 in the actual space 120 may be virtualized to be a twin model 112. The twin model 112 may include a software and/or hardware module to virtualize the factory control system 122 in the actual space 120 for conducting simulations through a computer or server. Accordingly, the twin model 112 may be referred to as a twin model module. However, the present disclosure is not limited to this term.

According to an embodiment, the twin model 112 may be controlled by a simulator 111. The simulator 111 may include a software or hardware module. The simulator 111 may be referred to as a simulator module. However, the present disclosure is not limited to this term.

According to an embodiment, multiple twin models 112 may respectively control multiple digital factories 113. The simulator 111 may create multiple digital factories 113 to conduct simulations (for example, virtualization through 3D modeling) by managing the multiple twin models 112. A user may access the simulator 111 through a user terminal 114. The user may input various configurations for conducting simulations with respect to the digital factories 113 by accessing the simulator 111 through the user terminal 114. Example embodiments in this regard are described in more detail below.

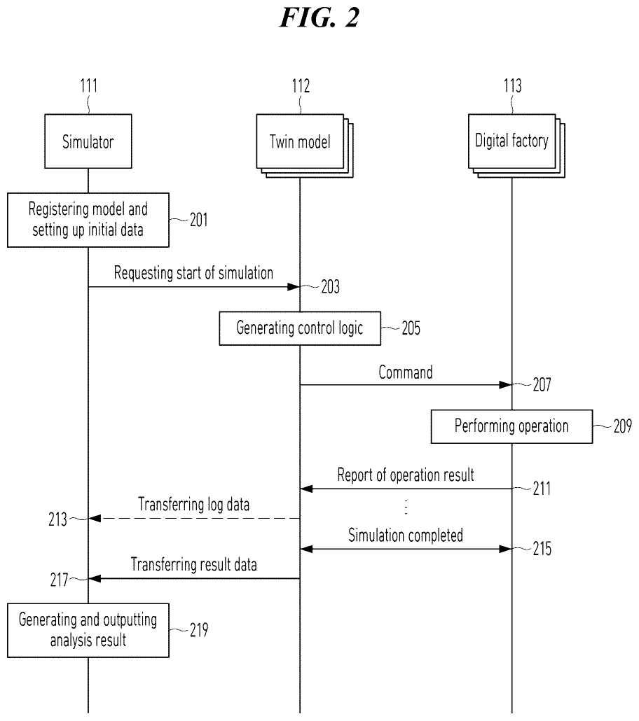

FIG. 2 is a flow diagram illustrating a control process of a digital twin system according to an embodiment of the present disclosure.

Referring to FIG. 2, according to an embodiment, in an operation or step 201, the simulator 111 may register a model for conducting simulations with respect to a digital factory and setting up initial data. In an operation or step 203, the simulator 111 may request the start of a simulation from a specific twin model 112 (for example, a first twin model) from among the multiple twin models. In an operation or step 205, the twin model 112 may generate control logic (or business logic) in response to the request from the simulator 111. According to another embodiment, the twin model 112 may generate the control logic before the simulator 111 requests the start of a simulation and confirm the already generated control logic in response to the request for the start of a simulation. The twin model 112 may sequentially generate commands for controlling a factory based on the generated control logic, and then transfer the generated commands to the relevant digital factory 113 (for example, a first digital factory) from among multiple digital factories in an operation or step 207. The digital factory 113 may receive the commands for controlling the factory from the twin model 112 and perform operations based on the received commands in an operation or step 209. For example, the digital factory 113 may transport products, operate a conveyor belt, or operate a robot according to the commands.

According to an embodiment, in an operation or step 211, the digital factory 113 may report in real time a result of the operations to the twin model 112 or the simulator 111. In an operation or step 213, the twin model 112 may transfer the result of the operations received from the digital factory 113 as log data to the simulator 111. After the digital factory 113 has performed the operations according to the commands based on the control logic as described above, the simulation may be terminated in an operation or step 215. When the simulation is terminated, the twin model 112 may transfer result data to the simulator 111 in an operation or step 217. The simulator 111 may generate a result of analyzing the simulation based on the log data and/or result data received from the twin model 112 or the digital factory 113, and may output the generated result in an operation or step 219.

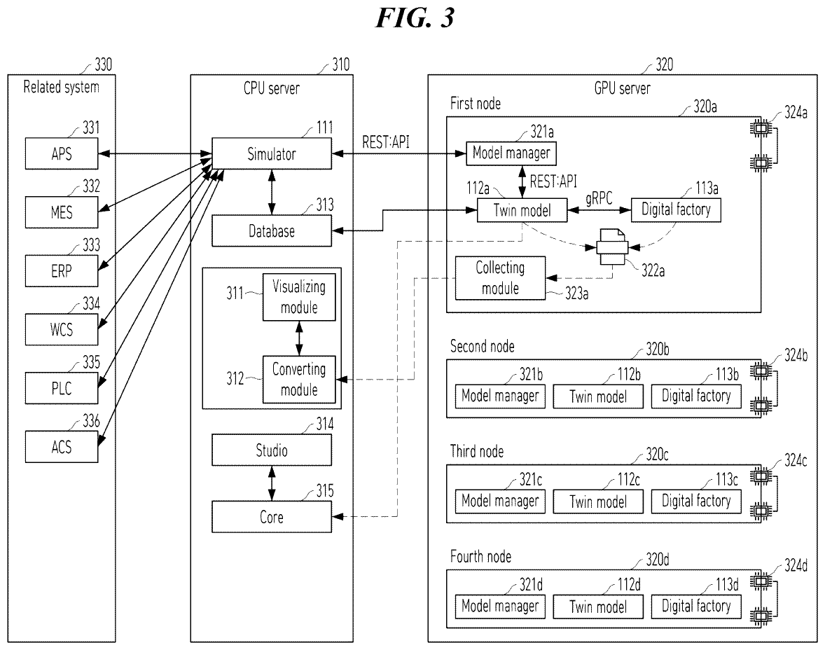

FIG. 3 is a block diagram illustrating a digital twin system, according to an embodiment of the present disclosure.

Referring to FIG. 3, a digital twin system according to an embodiment may include a central processing unit (CPU) server 310 and a graphics processing unit (GPU) server 320. Additionally, the CPU server 310 may operate in conjunction with an external related system 330 (for example, an Advanced Planning & Scheduling System (APS) (a production planning system) 331, a Manufacturing Execution System (MES) (a factory management system) 332, an Enterprise Resource Planning (ERP) 333, a Warehouse Control System (WCS) 334, a Programmer Logic Control (PLC) 335, or an Auto Control System (ACS) (a robot control system) 336). The CPU server 310 may include a simulator 111 and a database 313. Also, the CPU server 310 may further include a visualizing module 311, a converting module 312, a studio program 314, and a core program 315. The simulator 111 may communicate with the external related system 330 through an API gateway.

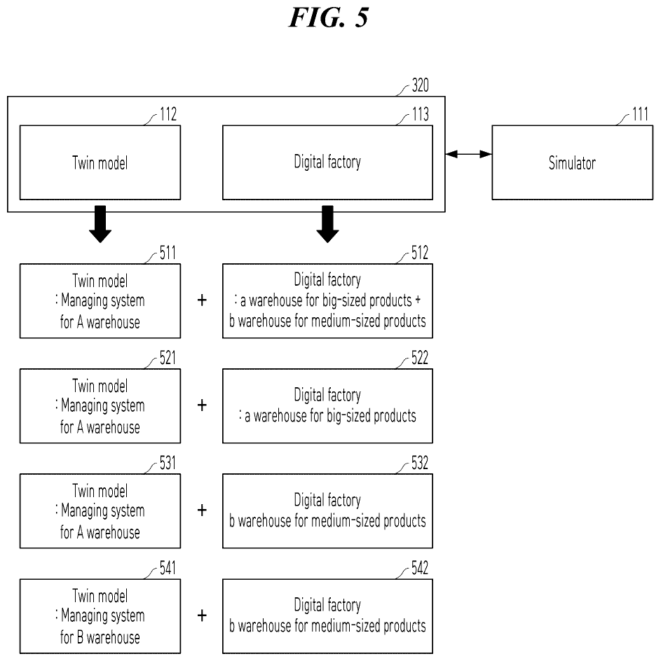

According to an embodiment, the GPU server 320 may comprise multiple twin models 112 and multiple digital factories 113. Each twin model 112 and each digital factory 113 may be connected with each other to conduct simulations with respect to a virtual factory. For example, the GPU server 320 may include multiple combinations of the twin models 112 and the digital factories 113 in order to conduct simulations with respect to multiple virtual factories. Examples in this regard, according to embodiments, are described in more detail below with reference to FIG. 5.

According to an embodiment, each twin model 112 and each digital factory 113 may communicate with each other using any one of interfaces, including a Remote Procedure Call (RPC) (for example, gRPC), a RestAPI, a Socket, a Kafka, and a Message Queue (MQ). For example, a first twin model 112a may communicate with a first digital factory 113a by an RPC interface, a second twin model 112b may communicate with a second digital factory 113b by an RPC interface, a third twin model 112c may communicate with a third digital factory 113c by an RPC interface, and a fourth twin model 112d may communicate with a fourth digital factory 113d by an RPC interface.

According to an embodiment, each twin model 112 may communicate with the simulator 111 of the CPU server 310 directly or through a model manager 321 as shown in FIG. 3. For example, the first twin model 112a may communicate with a first model manager 321a by a RESTful API and the first model manager 321a may communicate with the simulator 111 by a RESTful API. The second twin model 112b may communicate with a second model manager 321b by a RESTful API and the second model manager 321b may communicate with the simulator 111 by a RESTful API. The third twin model 112c may communicate with a third model manager 321c by a RESTful API and the third model manager 321c may communicate with the simulator 111 by a RESTful API. The fourth twin model 112d may communicate with a fourth model manager 321d by a RESTful API and the fourth model manager 321d may communicate with the simulator 111 by a RESTful API. In the embodiment described below, there is provided an example in which the first twin model 112a and the first digital factory 113a operate through the first model manager 321a, corresponding to a first node 320a. The same or similar operations may be conducted in the remaining nodes 320b, 320c, 320d.

According to an embodiment, the simulator 111 may send a message related to the conduct of a simulation to each twin model 112. For example, the simulator 111 may send a request message for the start, stop, restart, or status check of a simulation to each twin model 112. The request message may include at least one of a type of a module (for example, twin model (TM) or digital factory (DF)), an internet protocol (IP) address, a port, and build version information. Each twin model 112a, 112b, 112c, 112d from among the multiple twin models 112 may receive a request message from the simulator 111 and perform processing corresponding to the request.

According to an embodiment, the digital factories 113 may receive commands based on the control logic from the twin models 112 and perform operations corresponding to the received commands. Log data 322a, generated during a simulation conducted in the first twin model 112a or the first digital factory 113a, may be collected by a collecting module 323a and transferred to a converting module 312 of the CPU server 310. The converting module 312 of the CPU server 310 may convert the collected log data 322a into processible data. A visualizing module 311 may create visual images with result data of a simulation based on data converted by the converting module 312. According to various embodiments, at least one CPU 324 (for example, 324a, 324b, 324c, 324d) may be connected to each node in the GPU server 320 to process operations related to conduct of a simulation.

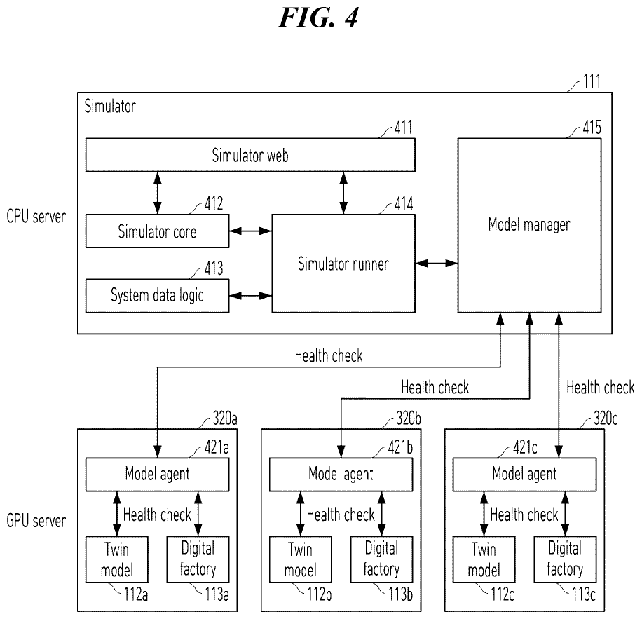

According to an embodiment, as shown in FIG. 3, at least one GPU server 320 may include multiple nodes 320a, 320b, 320c, 320d, configured to conduct simulations for various digital factories (for example, a 3D digital factory). In addition, according to an embodiment, a single simulator 111 included in a CPU server 310 may manage and control multiple nodes 320a, 320b, 320c, 320d configured to conduct simulations. For example, the simulator 111 may check and manage in real time the status of each simulation conducted in each of multiple nodes 320a, 320b, 320c, 320d of the GPU server 320 and control operations of each simulation. When rebooting the GPU server 320 due to its problems, even if the log-in to the server is impossible due to the absence of a server administrator, a simulation may be normally conducted by the simulator 111. According to an embodiment, a model agent may be developed in a form of at least two Windows services. For example, there may be provided one Windows service to communicate with the simulator 111 by a RESTful API and another Windows service to check whether an actual simulation process normally proceeds and then to perform drive or restart. Here, commands between the Windows services may be processed by Inter Process Communication (IPC) and Windows services installed in each node and a model manger to centrally control and monitor them may be involved. More detailed descriptions in this regard are presented below with reference to FIG. 4.

According to an embodiment, as shown in FIG. 3, Windows services implemented in the GPU server 320 may be automatically executed when the services are normally driven even if the log-on to the Windows services has not been made. Therefore, even when the GPU server 320 needs to be rebooted due to a specific reason and the log-in to the server is impossible due to the absence of a server administrator, the GPU server 320 may receive commands related to conduct of a simulation. In addition, since the simulation is a process executed by a Windows service, the simulation process may be directly controlled remotely (for example, by the simulator 111) even without direct access to a Windows server. According to an embodiment, the CPU server 310 may be a Linux server. However, the present disclosure is not limited thereto.

FIG. 4 is a block diagram illustrating a digital twin system, according to an embodiment of the present disclosure.

Referring to FIG. 4, a simulator 111 may be implemented in a CPU server. The simulator 111 may include a simulator web 411, a simulator core 412, a simulator data logic 413, a simulator runner 414, and a model manager 415. A GPU server may include multiple nodes 320a, 320b, 320c. Each node 320 may include a model agent 421, a twin model 112, and a digital factory 113. For example, a first node 320a may include a first model agent 421a, a first twin model 112a, and a first digital factory 113a. A second node 320b may include a second model agent 421b, a second twin model 112b, and a second digital factory 113b. A third node 320c may include a third model agent 421c, a third twin model 112c and a third digital factory 113c.

According to an embodiment, the simulator 111 may communicate with modules (for example, a twin model 112 or a digital factory 113) included in each node 320 directly or through the model manager 415. For example, the simulator runner 414 of the simulator 111 may conduct operations related to a simulation and the model manager 415 may perform connection or communication with each of the multiple nodes 320 to enable the multiple nodes 320 to share the functions.

According to an embodiment, the simulator 111 may perform a health check (normal operation check) of each node 320 by the model manager 415. For example, the simulator 111 may send a request message related to conduct of a simulation (for example, a request message including the start, stop, restart, or health check of a simulation) to each model agent 421 of each node 320 through the model manager 415. The request message may include at least one of a type of a module (for example, twin model (TM) or digital factory (DF)), an internet protocol (IP) address, a port, or build version information. Each twin model 112 may receive a request message from the simulator 111 and perform processing corresponding to the request. For example, each node 320 may check its status and report whether the node operates (for example, a result from a command for operation, re-operation, or stop) to the simulator 111.

FIG. 5 is a diagram illustrating combinations of twin models and digital factories, according to an embodiment of the present disclosure.

Referring to FIG. 5, when implementing a digital twin system according to an embodiment, various virtual factories may be implemented by separating modules for controlling factory systems and modules for virtualizing factories. For example, a twin model 112, that is a virtual representation of a factory control system, may generate a command for executing control logic (or business logic) and transfer the command to a digital factory 113. The digital factory 113, as a physical engine to execute the command received from the twin model 112, may virtualize the relevant factory and conduct a simulation. As such, various types of simulations may be conducted as shown in FIG. 5 by implementing an element in charge of control logic and an element in charge of executing commands in separate modules.

For example, a combination in which a managing system for an A warehouse is set to be a first twin model 511 and an a warehouse for big-sized products and a b warehouse for medium-sized products are set to be a first digital factory 512 may be simulated; a combination in which the managing system for the A warehouse is set to be a second twin model 521 and only the a warehouse for big-sized products is set to be a second digital factory 522 may be simulated; a combination in which the managing system for the A warehouse is set to be a third twin model 531 and only the b warehouse for medium-sized products is set to be a third digital factory 532 may be simulated; or a combination in which a managing system for a B warehouse is set to be a fourth twin model 541 and only the b warehouse for medium-sized products is set to be a fourth digital factory 542 may be simulated. The simulator 111 may combine the twin models 511, 521, 531, 541 and the digital factories 512, 522, 532, 542 in various ways.

As such, designing architectures for flexible simulations for factories is possible by implementing twin models, that are virtual representations of factory control systems, and digital factories, that are virtual representations of actual factories, in separate modules. For example, there may exist common logic or common facilities that may be applied to every factory in simulations. Here, separating an element in charge of logic and an element in charge of execution according to an embodiment enables using common logic or common facilities without implementing new logic or facilities for every factory simulation project. As described above, the twin model is a virtual representation of a factory control system of an actual system. The twin model may replicate logic of the system as well as data. In addition, instead of simply performing computation using algorithms, the twin model 112 may conduct a higher level of simulations by reflecting control logic (or business logic). The digital factory 113 may embody a 3D virtual factory based on a physical engine and construct a factory environment identical to the reality based on CAD drawings. According to an embodiment, by linking the twin model 112 and the digital factory 113 by an RPC communication interface, as described above, the twin model 112 may transfer commands to the digital factory 113 and the digital factory 113 may report a result based on the commands to the twin model 112.

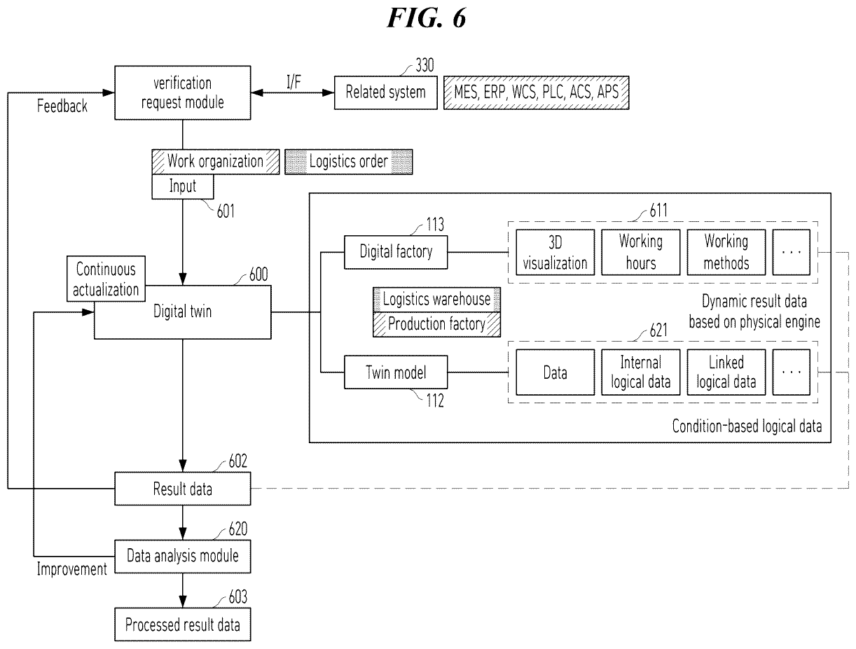

FIG. 6 is a diagram illustrating a process for a simulation of a factory, according to an embodiment of the present disclosure.

Referring to FIG. 6, for example, if the factory is a production factory, data related to work organization for simulations may be inputted 601 and if the factory is a logistics factory, data related to logistics orders for simulations may be inputted 601. As described above, a digital twin system 600 according to an embodiment may be implemented in separate modules of a twin model 112 and a digital factory 113. The twin model 112 may generate commands for operations in the digital factory 113 based on the inputted data (for example, control logic). The data processed in the twin model 112, that is condition-based logical data, may include internal logic data or linked logic data. The digital factory 113 may conduct simulations based on the commands received from the twin model 112. The data processed in the digital factory 113, that is dynamic result data based on a physical engine, may include data for 3D visualization, data related to working hours, data related to working methods, or the like. However, the present disclosure is not limited thereto.

According to an embodiment, result data 602 generated by the digital twin system 600 through simulation operations may become processed result data 603 by analysis and processing of a data analysis module 620. For example, the data generated in the digital twin system 600 may include an operation rate, an on-time component issue rate, an average processing time, or the like of each workshop in case of a logistics warehouse and may include a cell component supply time, a cell port component waiting time, or the like in case of a production factory. However, the present disclosure is not limited thereto. The data processed by the data analysis module 620 may include a minimum number of workers required for a daily production target, processible handling volume when a specific facility problem occurs, an optimum method for storing components in an automatic warehouse for production of various types of vehicles, or the like. However, the present disclosure is not limited thereto.

According to an embodiment, the result data 602 generated in the digital twin system 600 may be fed back to a verification request module to be verified and the verification request module may perform verification in conjunction with a related system 330 (for example, APS 331, MES 332, ERP 333, WCS 334, PLC 335, or ACS 336). The data analysis module 620 may input improved input values reflecting analysis results into the digital twin system 600 and this enables continuous actualization with respect to the simulations. In addition, the data analyzed and processed by the data analysis module 620 may be provided as grounds for decisions that may be reflected in a factory control system of an actual factory 120.

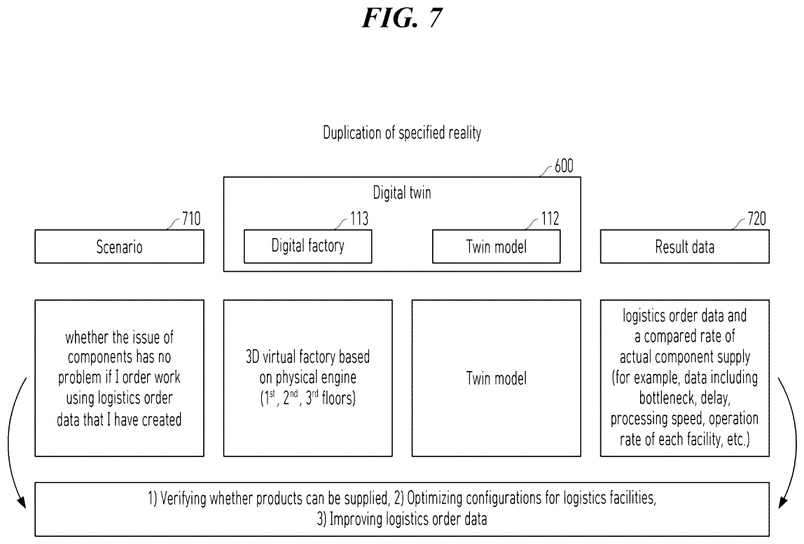

FIG. 7 is a diagram illustrating a concept of a simulation of a factory, according to an embodiment of the present disclosure.

Referring to FIG. 7, as described above, by constructing architectures for flexible factory simulations according to an embodiment, results from various scenarios may be confirmed or data may be verified using virtual spaces and simulators. For example, as described above, by establishing a similar environment regarding a desired scenario in a digital twin system and conducting a simulation, the result may be verified.

According to an embodiment, as an example of a scenario 710, in a case when a user wishes to confirm or verify “whether the issue of components has no problem if I order work using logistics order data that I have created”, as described above, the user may conduct a simulation using a twin model 112 and a digital factory 113 in a digital twin system 600 and verify result data. For example, as result data from this simulation, logistics order data and a compared rate of actual component supply (for example, data including bottleneck, delay, processing speed, operation rate of each facility, etc.) may be verified. By reviewing the result data, the user, who has conducted the simulation using the digital twin system 600, may verify whether products can be supplied and optimize configurations for logistics facilities. In addition, the user may improve the logistics order data after verifying the result data.

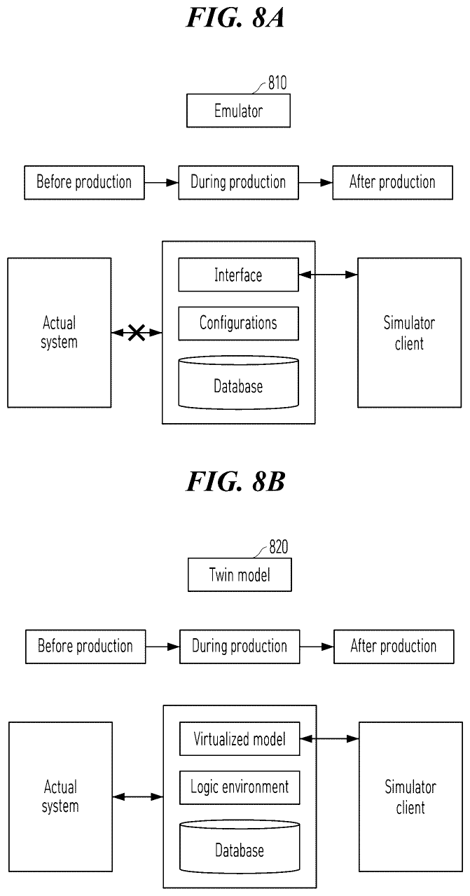

FIG. 8A is a diagram illustrating a concept of a simulation of a factory using an emulator, according to an embodiment of the present disclosure.

Referring to FIG. 8A, a simulation for a factory may be conducted using an emulator 810. For example, the emulator 810 may include an interface to communicate with a simulator client, configurations, and a data generator. The emulator 810 may include a data generating function and a responding function of the data generator so as to act as a mock-up during development. The emulator 810 may generate data suitable for a required application, which is generally usable. However, it could be difficult to apply the data to an actual system. Therefore, the data may be utilized before production, but it might not be utilized during or after production.

FIG. 8B is a diagram illustrating a concept of a simulation of a factory using a twin model, according to an embodiment of the present disclosure.

Referring to FIG. 8B, according to an embodiment, a simulation for a factory may be conducted using a twin model 820 as described above. For example, the twin model 820 may include a virtualization model, a logic environment, and a data generator. The twin model 820 is an exclusive model for a specific system and may replicate control logic of the system (for example, business logic) as well as data. The twin model 820 may be linked with an actual system. Therefore, the twin model 820 may virtualize a subject system in accordance with a purpose of a simulation. It may be used for confirming results of various scenarios for a specific system or verifying data.

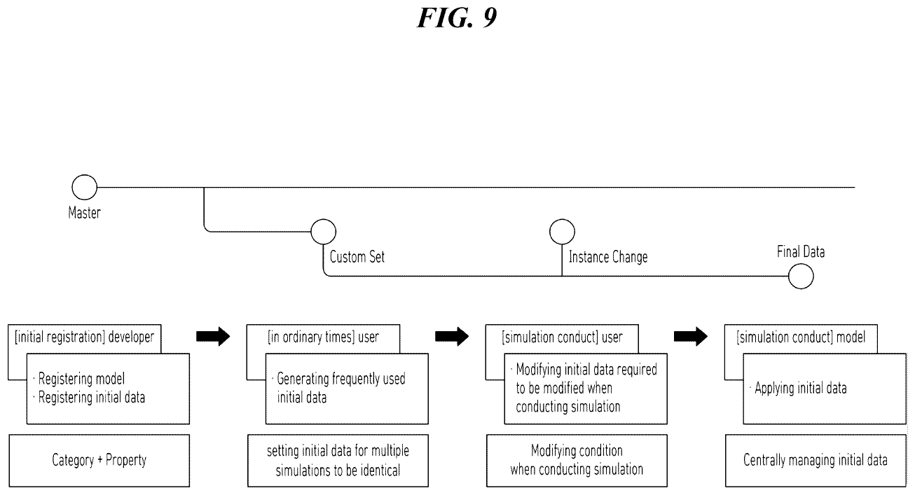

FIG. 9 is a diagram illustrating operations or steps of editing and managing configurations for each model, according to an embodiment of the present disclosure.

Referring to FIG. 9, according to an embodiment, a digital twin system may store, edit, and manage set values for each simulation model. For example, the digital twin system may set up simulations by managing various configurations. Properties of simulations may be managed with set values in order to conduct various simulations, and may be changed.

To manage the properties of the simulations and change them in various ways, an architecture may be necessary. According to an embodiment, initial data or initial data master may be set up depending on versions of models. The initial data may include categories and properties. A user may customize frequently used values by modifying the initial data. Values frequently used by the user may be referred to as a customized set (or custom set). However, the present disclosure is not limited to this term. Also, the user may newly set initial data for each simulation. Data set by the user for each simulation may be referred to as user initial data, but the present disclosure is not limited to this term.

According to an embodiment, the initial data master described above may be generated or set depending on versions of a simulation model. The initial data master may be set by model and/or version. For example, initial data master of a first twin model and a first digital factory may be set and registered as first initial data master. A twin model 112 and a digital factory 113 (or a virtual factory) may generate data including categories and properties as initial data and the data may be set using various set values. The categories may be segmented in accordance with characteristics of each simulation model. For example, when the category is a buffer capacity, the properties may include a conveyor, workshop, warehouse buffer, etc. When the category is a facility capacity, the properties may include the size of a workshop, the size of a buffer bay, the numbers of racks/lanes/floors/cells of a warehouse. When the category is an operation rule, the properties may include the number of tray pushes, the number of the maximum disposal, the number of the maximum issue.

According to an embodiment, the customized set described above may be acquired by modifying or changing only frequently used values in the initial data master. When conducting a simulation, a user may import and apply a corresponding customized set. For example, storing and managing the customized set enables setting initial data for multiple simulations to be identical. When the user wants to vary input files to manage them by simulation units, the customized set may be used. When the user wants to conduct simulations in different nodes, the customized set may be used. In addition, when there exists common data from among data changed when conducting a simulation, the customized set may be used. In such cases, the user may establish a customized set with a frequently used condition and, when conducting a simulation, import the established customized set to apply it to the simulation.

According to an embodiment, user initial data may be newly set for every simulation. For example, the user may change set values in the initial data master or the customized set and store it as user initial data for the relevant simulation. Such changed and stored user initial data may be mapped onto a simulation history (for example, simulation time, simulation identification number). The user initial data, which is a condition applied to only the relevant simulation when it is conducted, may not affect other simulations. Since the user initial data is linked with the simulation history to be stored, the simulation may be re-conducted with the same data.

According to an embodiment, when a simulation is conducted by a simulation model, initial data as described above may be applied. As described above, the initial data may be managed in an integrated manner by the simulator 111 and stored in the database 313. For example, instead of storing the initial data by a model installed in each node (for example, a twin model 112 or a digital factory 113), the simulator 111 may centrally manage the initial data in an integrated manner so that multiple nodes may utilize it as identical common data. In addition, since data utilized in each simulation model is centrally managed, the relevant model (for example, a twin model 112 or a digital factory 113) may be involved in only conduct of a simulation and concentrate thereon.

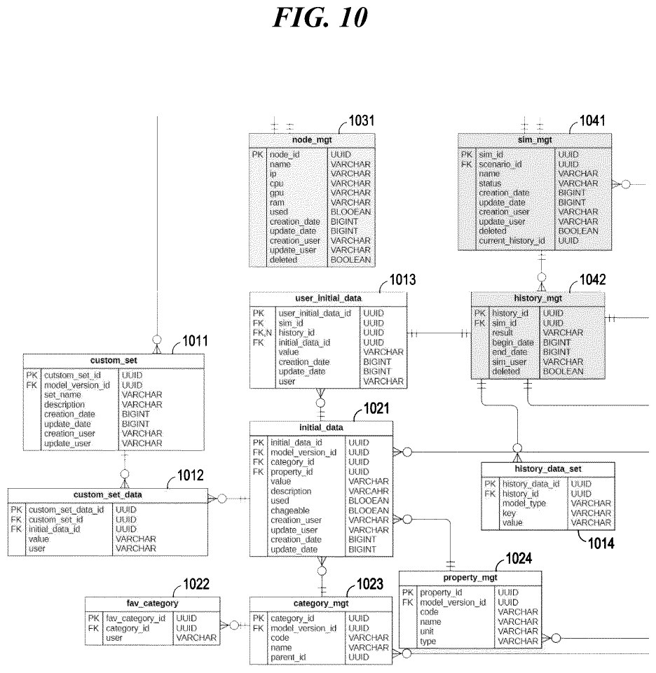

FIG. 10 is a diagram illustrating set values for configurations for each model, according to an embodiment of the present disclosure.

Referring to FIG. 10, according to an embodiment, configurations may be edited and managed for each simulation model as described by referring to FIG. 9. For example, a node management (node_mgt) 1031 may include a node ID (node_id), name (name), IP (ip), CPU name (cpu), GPU name (gpu), ram (ram), whether it is used (used), creation date (creation_date), update date (update_date), creation user (creation_user), update user (update_user), and whether it is deleted (deleted).

User initial data 1013 may include a user initial data ID (user_initial_data_id), simulation ID (sim_id), history ID (history_id), initial data ID (initial_data_id), value (value), creation date (creation_date), update date (update_date), and user (user).

A customized set 1011 may include a customized set ID (custom_set_id), model version ID (model_version_id), set name (set_name), description (description), creation date (creation_date), update date (update_date), creation user (creation_user), and update user (update_user).

Customized 1012 may include a customized set data ID (cumtom_set_data_id), customized set ID (custom_set_id), initial data ID (initial_data_id), value (value), and user (user).

Initial data (initial_data) 1021 may include an initial data ID (initial_data_id), model version ID (model_version_id), category ID (category_id), property ID (property_id), value (value), description (description), whether it is used (used), whether it is changeable (changeable), creation user (creation_user), update user (update_user), creation date (creation_date), and update date (update_date).

A simulation manager (sim_mgt) 1041 may include a simulation ID (sim_id), scenario ID (scenario_id), name (name), status (status), creation date (creation_date), update date (update_date), creation user (creation_user), update user (update_user), whether it is deleted (deleted), and current history ID (current_history_id).

A history manager (history_mgt) 1042 may include a history ID (history_id), simulation ID (sim_id), result (result), beginning date (begin_date), end date (end_date), simulation user (sim_user), and whether it is deleted (deleted).

A history data set (history_data_set) 1014 may include a history data ID (history_data_id), history ID (history_id), model type (model_type), key (key), and value (value).

A category manager (category_mgt) 1023 may include a category ID (category_id), model version ID (model_version_id), code (code), name (name), and parent ID (parent_id). A favorite category (fav_category) 1022 may include a favorite category ID (fav_category_id), category ID (category_id), and user (user). A property manager (property_mgt) 1024 may include a property ID (property_id), model version ID (model_version_id), code (code), name (name), unit (unit), and type (type).

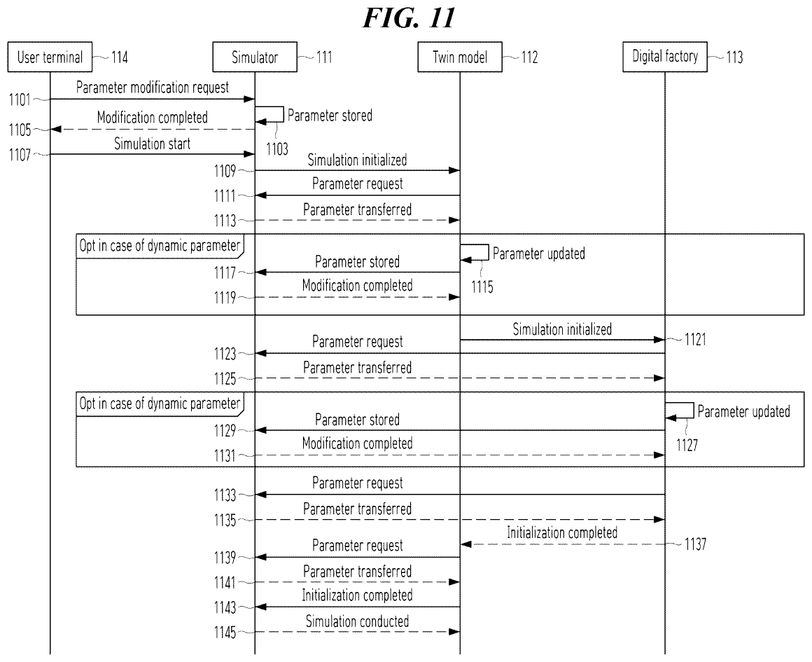

FIG. 11 is a flow diagram illustrating operations or steps of editing and managing settings for each model, according to an embodiment of the present disclosure.

Referring to FIG. 11, according to an embodiment, a simulation may be initialized. In an operation or step 1101, a user may request a modification of a parameter (for example, configuration) from a simulator 111 (for example, a simulator server) through a user terminal 114. In an operation or step 1103, the simulator 111 may store the parameter. In an operation or step 1105, the simulator 111 may notify completion of the modification to the user terminal 114.

According to an embodiment, the user may request the start of a simulation from the simulator 111 through the user terminal 114 in an operation or step 1107. The simulator 111 may request an initialization of the simulation from a twin model 112 in an operation or step 1109. The twin model 112 may request a parameter from the simulator 111 in response to the request of the simulator 111 in an operation or step 1111. The simulator 111 may transfer the corresponding parameter to the twin model 112 in response to the request in an operation or step 1113. Here, if the parameter is a dynamic parameter, the twin model 112 may update the transferred parameter in an operation or step 1115. The twin model 112 may transfer the updated parameter to the simulator 111 and request the storage of the updated parameter from the simulator 111 in an operation or step 1117. The simulator 111 may store the updated parameter and send a message indicating completion of the modification to the twin model 112 in an operation or step 1119.

According to an embodiment, the twin model 112 may request an initialization of a simulation from a digital factory 113 after the update of the parameter has been completed in an operation or step 1121. The digital factory 113 may request a parameter from the simulator 111 in response to the request for the initialization in an operation or step 1123. The simulator 111 may transfer the corresponding parameter to the digital factory 113 in response to the request in an operation or step 1125. Here, if the parameter is a dynamic parameter, the digital factory 113 may update the transferred parameter in an operation or step 1127. The digital factory 113 may transfer the updated parameter to the simulator 111 and request the storage of the updated parameter from the simulator 111 in an operation or step 1129. The simulator 111 may store the updated parameter and send a message indicating completion of the modification to the digital factory in an operation or step 1131. The digital factory 113 may request a parameter from the simulator 111 after the modification of the parameter has been completed in an operation or step 1133. The simulator 111 may transfer the corresponding parameter to the digital factory 113 in response to the request in an operation or step 1135. The digital factory 113 that has received the parameter may send a message indicating completion of the initialization to the twin model 112 in an operation or step 1137.

According to an embodiment, after having received the message indicating completion of the initialization, the twin model 112 may request a parameter from the simulator 111 in an operation or step 1139. The simulator 111 may transfer the corresponding parameter to the twin model 112 in response to the request in an operation or step 1141. The twin model 112 that has received the parameter may send a message indicating completion of the initialization to the simulator 111 in an operation or step 1143. The simulator 111 that has received the message indicating completion of the initialization may send a message indicating conduct of the simulation in an operation or step 1145. The twin model 112 that has received the message indicating conduct of the simulation may conduct the simulation in conjunction with the digital factory 113.

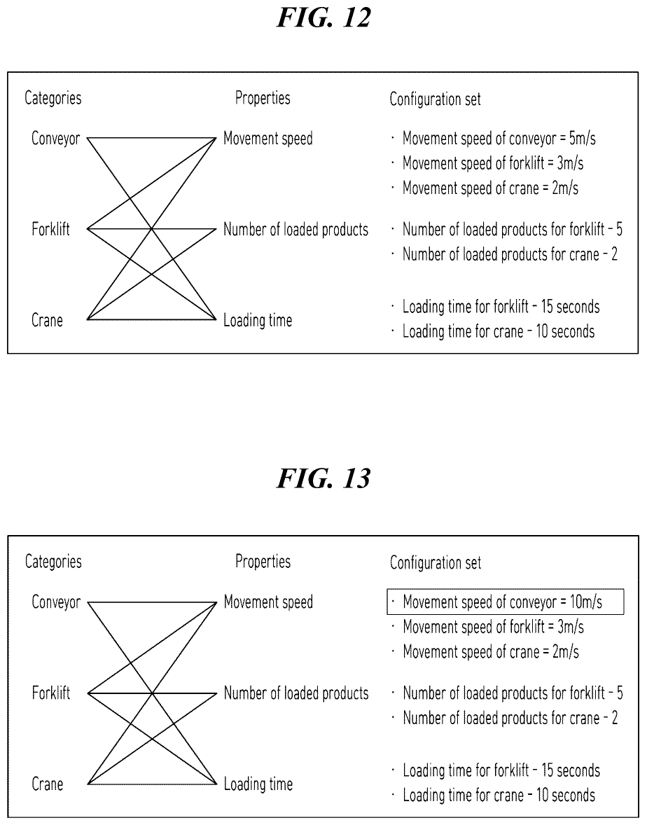

FIG. 12 is a diagram illustrating a structure for generating a set of configurations, according to an embodiment of the present disclosure.

Referring to FIG. 12, according to an embodiment, configuration sets may be created by combinations of categories and properties. For example, the categories may include a conveyor, a forklift, and a crane. The properties may include the movement speed, the number of loaded products, and the loading time.

According to an embodiment, the conveyor may be mapped onto the movement speed or the loading time. The forklift or the crane may be mapped respectively onto the movement speed, the number of loaded products, or the loading time. As shown FIG. 12, a configuration set, including the movement speed of the conveyor set to 5 m/s, the movement speed of the forklift set to 3 m/s, and the movement speed of the crane set to 2 m/s, may be established. The number of loaded products for the forklift may be set to 5 and the number of loaded products for the crane may be set to 2. The loading time for the forklift may be set to 15 seconds and the loading time for the crane may be set to 10 seconds.

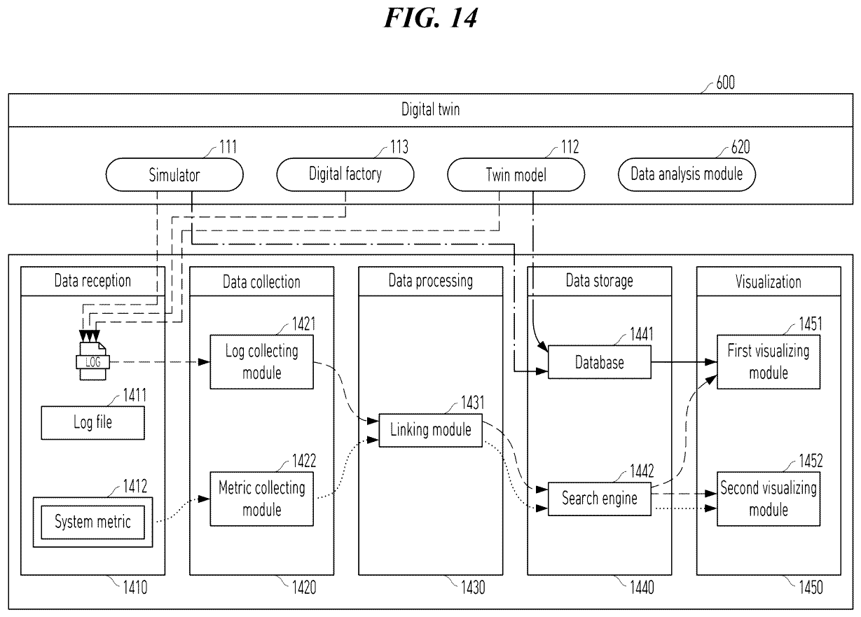

The configuration sets as described above and shown in FIG. 12 may be stored as a history as simulations are conducted. Here, by modifying a specific set, another customized set may be created using a branch structure. Examples of creating customized sets using a branch structure, according to embodiments, are described in more detail below with reference to FIG. 13.

FIG. 13 is a diagram illustrating editing of sets of configurations according to an embodiment of the present disclosure.

Referring to FIG. 13, according to an embodiment, a new customized set may be created by modifying the movement speed of the conveyor from 5 m/s to 10 m/s in the configuration set of FIG. 12.

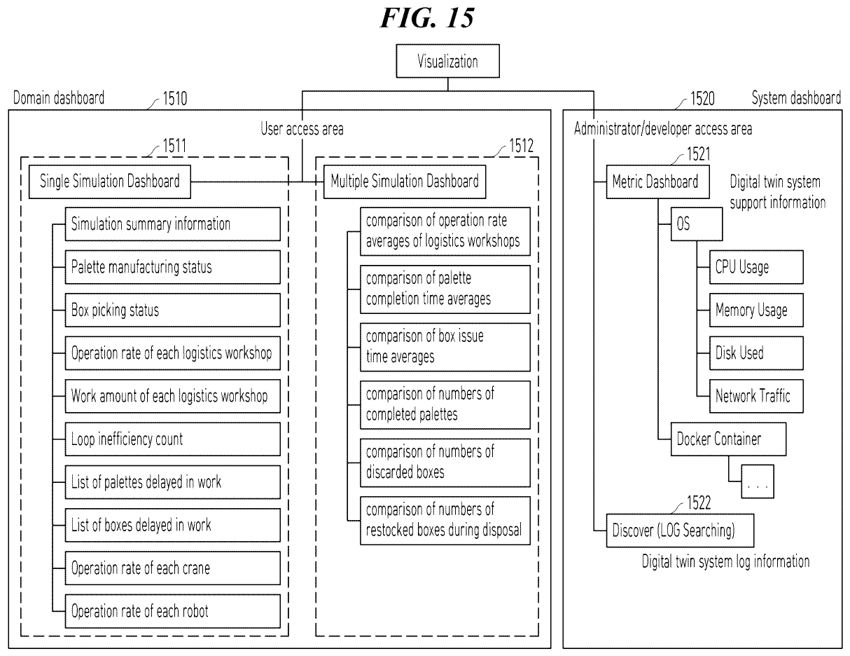

FIG. 14 is a diagram illustrating a flow of processing data, according to an embodiment of the present disclosure.

Referring to FIG. 14, according to an embodiment, a digital twin system 600 may include a simulator 111, a twin model 112, a digital factory 113, and a data analysis module 620.

According to an embodiment, in a data reception operation or step 1410, a log file 1411 may be created with log data generated in real time in the simulator 111, the data receiving twin model 112, and the digital factory 113. In a data collection operation or step 1420, a data collecting module 1421 may collect log data. For example, the data collecting module 1421 may be implemented by an application program such as ‘Filebeat’, but the present disclosure is not limited thereto. In the aforementioned data collection operation or step 1420, a metric collecting module 1422 may collect system metrics 1412. For example, the metric collecting module 1422 may be implemented by an application program such as ‘Metricbeat’. However, the present disclosure is not limited thereto.

According to an embodiment, in a data processing operation or step 1430, a linking module 1431 may process the log data collected by the log collecting module 1421 and the metric data collected by the metric collecting module 1422 by linking these two pieces of data with each other. For example, the linking module 1431 may be implemented by an application program such as ‘Logstash’. However, the present disclosure is not limited thereto.

According to an embodiment, in a data storage operation or step 1440, a data base 1441 may store simulation result data generated by the simulator 111 and the twin model 112. In the data storage operation or step 1440, a search engine 1442 may receive the log data and the metric data from the linking module 1431 and perform a search based on these pieces of data. For example, the search engine 1442 may be implemented by an application program such as ‘Elasticsearch’. However, the present disclosure is not limited thereto.

According to an embodiment, in a visualization operation or step 1450, a first visualizing module 1451 may visually display an analysis result based on the simulation result data stored in the database 1441 and the log data received by the search engine 1442. For example, the first visualizing module 1451 may be implemented by an application program such as ‘Grafana’, but the present disclosure is not limited thereto. In the visualization operation or step 1450, a second visualizing module 1452 may receive the log data and the metric data from the search engine 1442 and visually display an analysis result. For example, the second visualizing module 1452 may be implemented by an application program such as ‘Kibana’, but the present disclosure is not limited thereto.

According to an embodiment, the log data collected in the data collection operation or step and the simulation results of FIG. 14 are as in Table 1 below.

TABLE 1

| Name of | | | |
|---|---|---|---|
| Property | Type | Description | Example |
| node_name | string | simulation node name | NODE-1 |
| node_id | uuid | simulation node ID | 029853a7-5b58-4142-8aa5- |
| | | | 8fa4cb461462 |
| sim_id | uuid | simulation ID | 5b9a4613-355d-4d7b-8174- |
| | | | 3cd3def06bce |
| app_type | string | application type | TM |
| | | (DF: virtual factory, | |
| | | TM: twin model) | |
| app_name | string | application name | LCS |
| caller | string | actant of call | com.hae.df.ECS.getPartInfo |
| call_type | string | type of called function | 1646282172407 |
| call_name | string | called function | com.hae.df.PartInfoManager.getPartInfo |
| call_time | long | time point of call | 1646282172407 |
| | | (millisecond) | |
| call_parameter | string | parameters of called function | { |
| | | | part_no: “6750-GI900”, |
| | | | part_type: “B” |
| call_return | string | return value of called | } |
| | | function | part_no: “6750-GI900”, |
| | | | part_name: “ASSY MIRROR LF”, |
| | | | part_type: “B”, |
| | | | part_lane: [2, 3, 4] |
| | | | } |
| info | string | additional information | { |
| | | | rpc_name: “ArravalGtp”, |
| | | | rpc_parameter: {?? |
| | | | } |

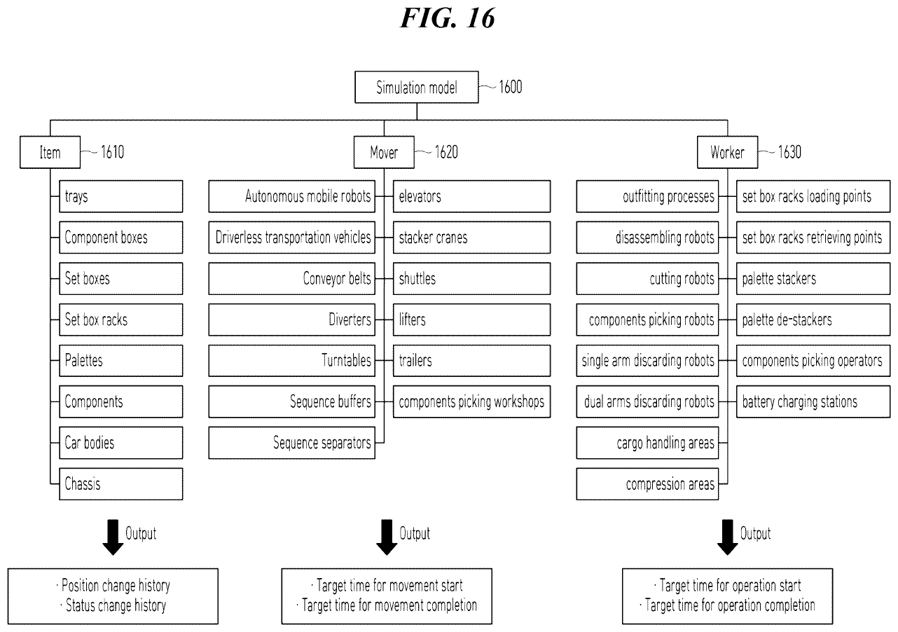

FIG. 15 is a diagram illustrating a method of processing data, according to an embodiment of the present disclosure.

Referring to FIG. 15, data visualized in the visualization operation or step 1450 as described above by referring to FIG. 14 may be divided into data of a domain dashboard 1510 and data of a system dashboard 1520. The domain dashboard 1510, which is a user access area, may be divided into a single simulation dashboard 1511 and a multiple simulation dashboard 1512.

According to an embodiment, the single simulation dashboard 1511 may include simulation summary information, palette manufacturing status, box picking status, an operation rate of each logistics workshop, a work amount of each logistics workshop, a loop inefficiency count, a list of palettes delayed in work, a list of boxes delayed in work, an operation rate of each crane, an operation rate of each robot, etc. The multiple simulation dashboard 1512 may include a comparison of operation rate averages of logistics workshops, a comparison of palette completion time averages, a comparison of box issue time averages, a comparison of numbers of completed palettes, a comparison of numbers of discarded boxes, and a comparison of numbers of restocked boxes during disposal.

According to an embodiment, the system dashboard 1520, which is an administrator or a developer access area, may include a metric dashboard 1521 and a discover 1522. The metric dashboard 1521 may include information regarding an operating system (OS) and a Docker Container as digital twin system support information. The information regarding the OS may include CPU usage, memory usage, disk usage, network traffic, etc. The information regarding the discover 1522 may include digital twin system log information.

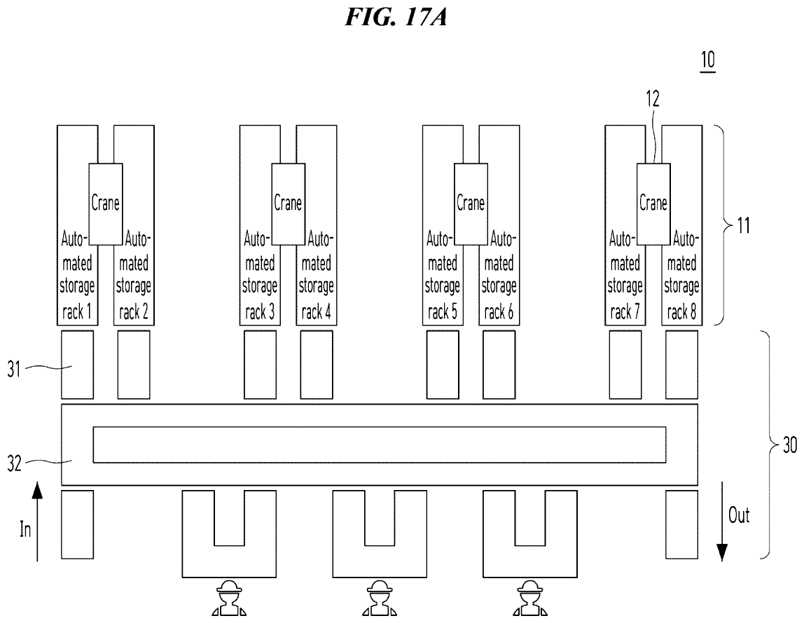

FIG. 16 is a diagram illustrating a method of generating indexes of a simulation result, according to an embodiment of the present disclosure.

Referring to FIG. 16, as described above, simulation result indexes (for example, logistics simulation result indexes) may be created based on log data collected as a simulation is conducted. Here, for comparing a simulation result with an actual operation result, numerical values, acquired during a simulation as well as result values after completion of the simulation, may also be main indexes. According to an embodiment, for the storage and indexation of values acquired during a simulation, whenever communication between the twin model 112 and the digital factory 113 is performed during a simulation, the relevant values may be recorded in a predetermined log data format and the method name, time, status, position, etc. may be verified from log data to make them as indexes. According to an embodiment, when creating a simulation model, data may be divided into data regarding items 1610, data regarding movers 1620, and data regarding workers 1630 and these pieces of data may be combined. Indexes may be generated by utilizing the combined data when conducting a simulation.

According to an embodiment, the log data format may be “node_name|node_id|sim_id|app_type|app_name|caller|call_type|call_name|call_time|call_parameter|call_return|info”. However, the present disclosure is not limited thereto.

Here, as a first example, an index may be created by searching for an operation with a method name in the ‘caller’ or ‘call_name’ and basing on the time when the operation is performed. As a second example, an index for each workshop may be created by searching for an operation with a method name in the ‘caller’ or ‘call_name’ and a place where the operation is performed in the ‘call_parameter’. As a third example, an index for each facility may be created by searching for an operation with a method name in the ‘caller’ or ‘call_name’ and a facility in the ‘call parameter’.

According to an embodiment, items 1610 of FIG. 16 may include trays, component boxes, set boxes, set box racks, palettes, components, car bodies, chassis, etc. A position change history or a status change history may be identified based on the items 1610. Movers 1620 may include autonomous mobile robots, driverless transportation vehicles, conveyor belts, diverters, turntables, sequence buffers, sequence separators, elevators, stacker cranes, shuttles, lifters, trailers, and components picking workshops. A target time for movement start and a target time for movement completion may be identified based on the mover 1620. Workers 1630 may include outfitting processes, disassembling robots, cutting robots, components picking robots, single arm discarding robots, dual arms discarding robots, cargo handling areas, compression areas, set box racks loading points, set box racks retrieving points, palette stackers, palette de-stackers, components picking operators, and battery charging stations. A target time for operation start and a target time for operation completion may be identified based on the workers 1630.

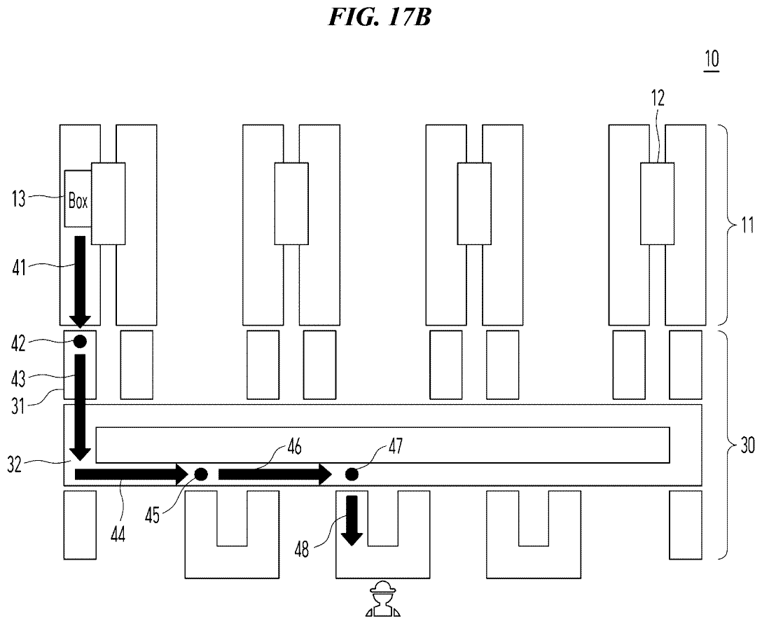

Hereinafter, according to an embodiment, a system and a method for controlling conveyors in a virtual environment that enables controlling conveyors virtualized in a digital twin system are described in detail with reference to FIG. 17A to FIG. 23.

FIGS. 17A and 17B are diagrams illustrating a system for controlling conveyors in a virtual environment according to an embodiment of the present disclosure.

Referring to FIGS. 17A and 17B, a virtual factory in a virtual environment according to an embodiment may include a conveyor 10 (or a conveyor system). On the conveyor 10, a product 13 (for example, a product box) may be transported from a starting position 40 to an arrival position 50. For example, the virtual factory in the virtual environment may conduct a simulation for movements or flows of products using a virtualized conveyor 10.

According to an embodiment, the conveyor 10 in the virtual environment as described above may be created by a digital factory 113 (for example, a digital factory module). The conveyor 10 created by the digital factory module may be controlled by a twin model 112 (for example, a twin model module), that is a virtual representation of a control system.

According to an embodiment, the virtualized conveyor 10 may comprise multiple paths 30 (or roads) obtained by segmenting the conveyor based on joints 41, 43, 45, 47. A product 13 (for example, a product box) placed in a starting position on the conveyor 10 may be delivered to an arrival position by being transported on the multiple paths 30. For example, a transportation route from the starting position to the arrival position may be formed by the multiple paths 30 obtained through segmentation based on the joints 41, 43, 45, 47.

According to an embodiment, when the product 13 is being transported through the multiple paths 30 included in the conveyor 10, the twin model module may verify in real time whether the distance of the product to a preceding product is within a predetermined range. When the distance to the preceding product is within the predetermined range, the twin model module may control the product in transportation to stop by control logic of the twin model module. Here, the predetermined range may correspond to a safety distance set for preventing collision with the preceding product.

According to an embodiment, the multiple paths 30 may include at least one straight path 31 (for example, a straight conveyor) and at least one turning path 32 (or curved path) (for example, a turning conveyor). The twin model module may set at least one of a length, an angle of gradient, or a moving speed for each straight path 31 to conduct simulations for product flows corresponding to those in an actual factory. Additionally, the twin model module may set at least one of a turning section, turning angle, and moving speed for each turning path 32 to conduct simulations for product flows corresponding to those in an actual factory. For example, the twin model module may set a transportation route for the product 13 transported by the conveyor 10 based on a combination of the straight path 31 and the turning path 32.

According to an embodiment, in the joints 41, 43, 45, 47 disposed between paths 31, 32, a direction changing unit for changing directions of the product (for example, a diverter or converter) may be disposed. The product 13 transported on the conveyor 10 may be controlled in its heading direction by control of the twin model module so as to go straight or to change its direction by the direction changing unit. According to an embodiment, the direction changing unit may include a bar code or a bar code reader. The bar code may include information on whether to change directions. Through the bar code or the bar code reader, whether to change the moving direction of the product or whether to move the product straight without direction change may be determined.

According to an embodiment, when it is verified that the product in transportation is not a target for direction change as a result of bar code scanning, the twin model module may control the product in transportation to go straight by the control logic. In addition, when it is verified that the number of products on an entrance section of the conveyor is equal to or higher than a predetermined number as a result of bar code scanning, the twin model module may control the product in transportation to go straight by the control logic. For example, the twin model module may control products to enter the entrance section only when the number of products (for example, product boxes) on the entrance section of the conveyor is less than the maximum allowable number. In this way, the buffer amount of the conveyor may be managed.

According to an embodiment, when it is verified that it is not the turn for the product to enter as a result of bar code scanning (i.e., when it is verified that the product in transportation is not to enter the conveyor), the twin model module may control the product in transportation to go straight by the control logic. When it is verified that the product in transportation is a target for direction switch as a result of bar code scanning, the twin model module may control the product in transportation to change its direction by the control logic. For example, the product in transportation on the conveyor may also move from the second floor to the third floor by the direction changing unit.

For example, referring to FIG. 17B, a product 13 stacked in an automated storage 11 may be downwardly moved 40 by a crane 12 from a stacked position and be placed on a straight path 31. When the product 13 approaches a first join 41, a destination (for example, an arrival position) of the product 13 may be verified using a bar code disposed in the first joint 41. By such a verification, the product 13 may go straight 42 in the first joint 41. When the product 13 approaches a second joint 43 by going straight 42, whether to change directions may be determined through a bar code disposed in the second joint 43. By such a verification, the product 13 may be turned 44 in the second joint 43. When the product 13 approaches a third joint 45 by being turned 44, whether to change directions may be determined through a bar code disposed in the third joint 45. By such a verification, the product 13 may go straight 46 in the third joint 45. When the product 13 approaches a fourth joint 47 by going straight 46, whether to change directions may be determined through a bar code disposed in the fourth joint 47. By such a verification, the product 13 may be turned 50 in the fourth joint 47. By being turned 50, the product 13 may arrive at the destination.

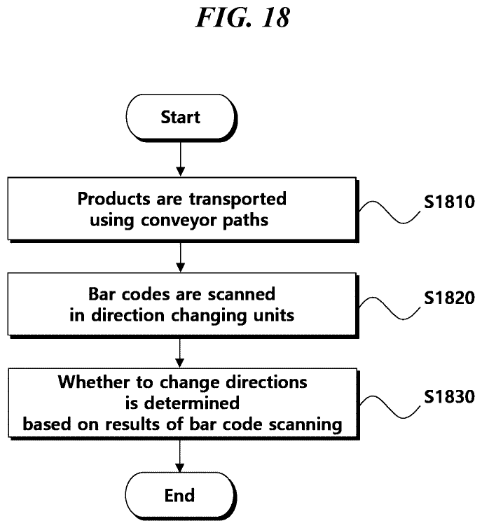

FIG. 18 is a flow diagram illustrating a control process of a conveyor according to an embodiment of the present disclosure.

Referring to FIG. 18, according to an embodiment, the twin model module may transport products through the conveyor paths 31, 32 in an operation or step S1810.

According to an embodiment, the twin model module may control that bar codes are scanned in direction changing units (for example, diverters or converters) disposed between multiple paths 31, 32 obtained by segmentation based on joints in an operation or step S1820.

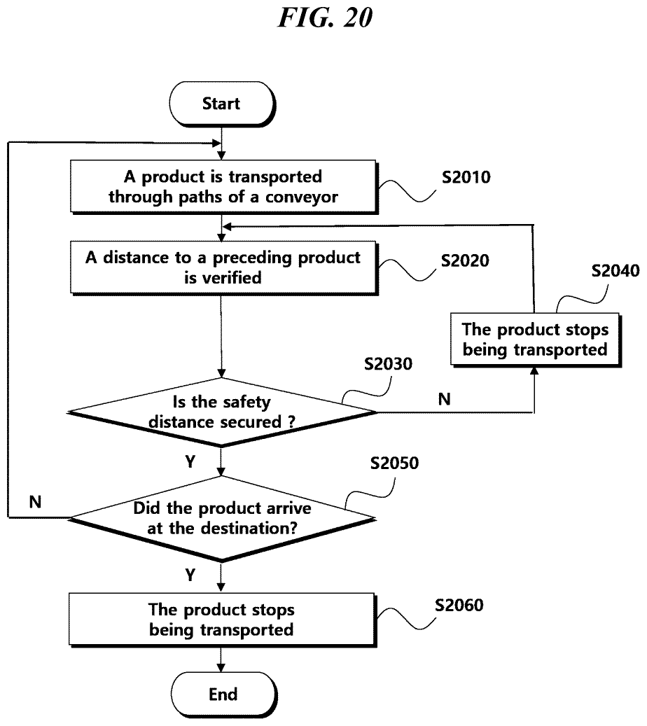

According to an embodiment, the twin model module may determine whether to change directions based on results of bar code scanning in an operation or step S1830. More detailed descriptions are made below with reference to FIG. 20 to FIG. 23.

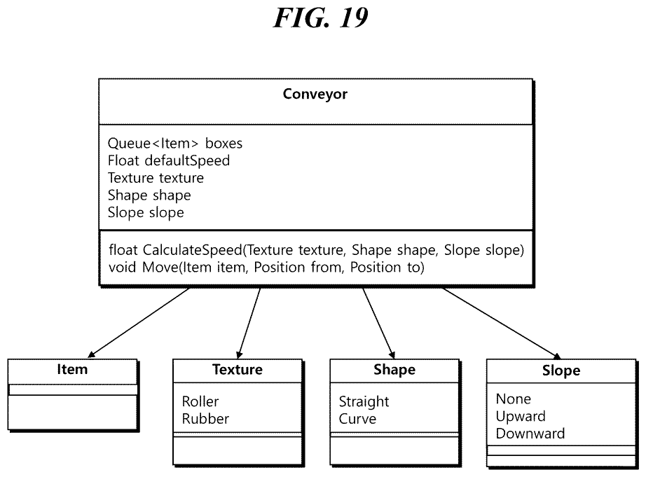

FIG. 19 is a diagram illustrating program logic for controlling a conveyor in a virtual environment according to an embodiment of the present disclosure.

Referring to FIG. 19, according to an embodiment, logic to determine transportation of items in the twin model module may be determined based on at least one of textures, shapes, or slopes of a conveyor 10. For example, the textures may include the texture of a roller or rubber. However, the present disclosure is not limited thereto. The shapes may include a straight or a curve. However, the present disclosure is not limited thereto. The slopes may include no slope (none), an upward slope (upward), and a downward slope (downward). However, the present disclosure is not limited thereto.

According to an embodiment, the moving speed of an item may be updated by an algorithm described in Table 2.

```
TABLE 2
public float CalculateSpeed(Texture texture, Shape shape, Slope slope) {
  float calculatedSpeed = defaultSpeed; // A default speed is the speed of a
conveyor where the texture is that of rollers, the shape is straight, and the slope is
none.
  if(texture == Texture.Rubber) {
    calculatedSpeed * 2; // If the texture is that of rubber, increase the speed
to be twice the default speed.
}
  if(shape == Shape.Curve) {
    calculatedSpeed * 0.8; // If the shape is curve, decrease the speed by 20%.
}
  if(slope== Slope.Upward) {
    calculatedSpeed * 0.7; // If the slope is upward, decrease the speed by 30%.
}
  else if(slope== Slope.Downward) {
    calculatedSpeed * 1.3; // If the slope is downward, increase the speed by
30%.
}
  return calculatedSpeed;
}
```

For example, referring to Table 2 in the above, the moving speed of an item may be processed by “CalculateSpeed(Texture texture, Shape shape, Slope slope)”.

Hereinafter, with reference to FIGS. 20-23, a process to determine whether to change directions based on results of scanning of bar codes included in the direction changing units in the twin model module according to an embodiment is described.

FIG. 20 is a flow diagram illustrating a control process of a conveyor according to an embodiment of the present disclosure.

Referring to FIG. 20, according to an embodiment, the twin model module may transport a product (or a product box) through paths of a virtualized conveyor in an operation or step S2010.

According to an embodiment, the twin model module may verify the distance of the product to a preceding product in an operation or step S2020. When the distance to the preceding product is equal to or greater than a predetermined distance as a result of the verification, it may be determined that a safety distance is secured in an operation or step S2030. When it is determined that the safety distance is secured, the product may keep moving. When the product in transportation arrives at a destination, the twin model module may control the product to stop moving in operations or steps S2050, 2060.

According to an embodiment, when the distance to the preceding product is less than the predetermined distance as a result of the verification of the distance to the preceding product, the twin model module may determine that the safety distance is not secured and may temporarily stop the transportation of the product in an operation or step S2040. The twin model module may verify in real time the distance to the preceding product and, when the distance to the preceding product is verified to be equal to or greater than the predetermined distance, may re-transport the product that has been stopped.

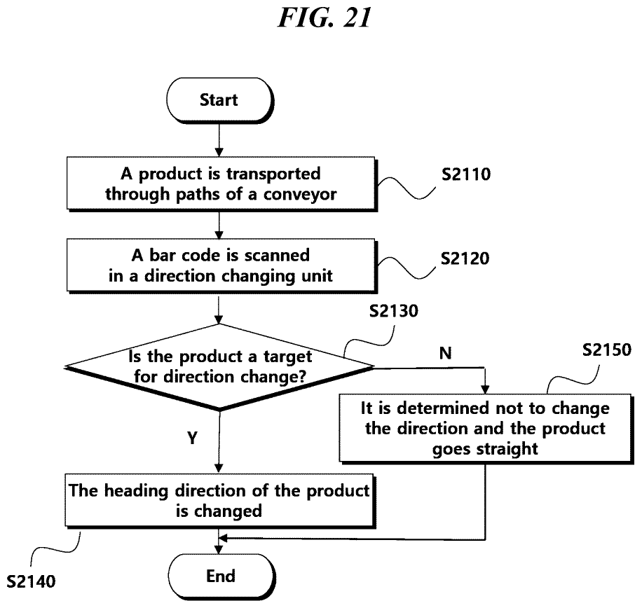

FIG. 21 is a flow diagram illustrating a control process of a conveyor according to an embodiment of the present disclosure.

Referring to FIG. 21, according to an embodiment, the twin model module may transport a product (or a product box) through paths of a virtualized conveyor in an operation or step S2110.

According to an embodiment, the twin model module may control that bar codes are scanned in direction changing units in an operation or step S2120. When it is verified that the product is a target for direction change as a result of bar code scanning, the twin model module may change the direction of the product in operations or steps S2130, S2140. On the contrary, when it is verified that the product is not a target for direction change as a result of bar code scanning, the twin model module may control the product to go straight without direction change in operations or steps S2130, S2150.

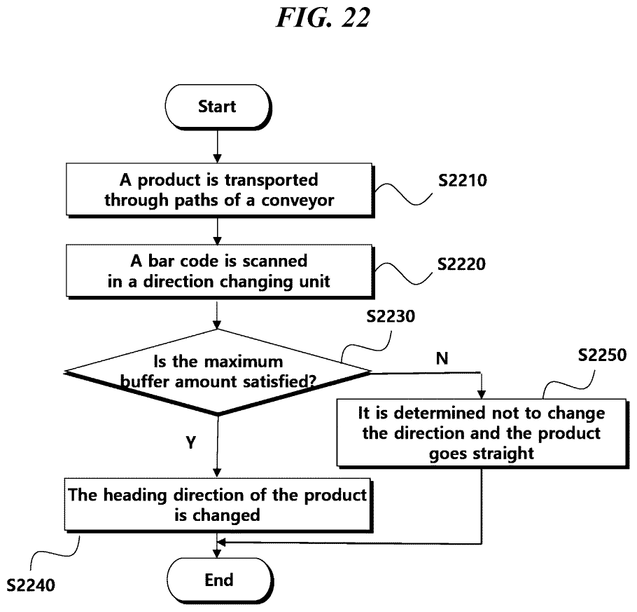

FIG. 22 is a flow diagram illustrating a control process of a conveyor according to an embodiment of the present disclosure.

Referring to FIG. 22, according to an embodiment, the twin model module may transport a product (or a product box) through paths of a virtualized conveyor in an operation or step S2210.

According to an embodiment, the twin model module may control that bar codes are scanned in direction changing units in an operation or step S2220. When the number of products on an entrance section of the conveyor satisfies the maximum buffer amount (for example, the number is less than the maximum buffer amount) as a result of bar code scanning, the control logic of the twin model module may change the heading direction of the product to the entrance section in operations or steps S2230, S2240. On the contrary, when the number of products on an entrance section of the conveyor does not satisfy the maximum buffer amount (for example, the number is equal to or greater than the maximum buffer amount), the control logic of the twin model module may control the product in transportation not to enter the entrance section, but to go straight in operations or steps S2230, S2250.

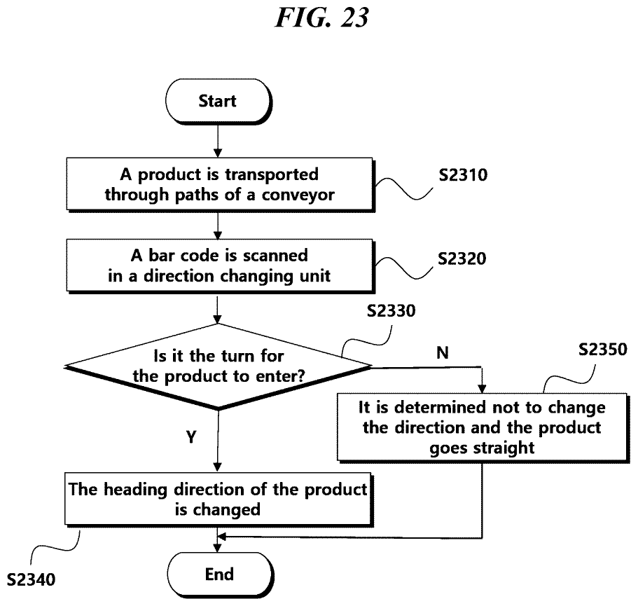

FIG. 23 is a flow diagram illustrating a control process of a conveyor according to an embodiment of the present disclosure.

Referring to FIG. 23, according to an embodiment, the twin model module may transport a product (or a product box) through paths of a virtualized conveyor in an operation or step S2310.

According to an embodiment, the twin model module may control that bar codes are scanned in direction changing units in an operation or step S2320. When it is the turn for the product to enter the relevant entrance section as a result of bar code scanning, the control logic of the twin model module may change the heading direction of the product to the entrance section in operations or steps S2330, S2340. On the contrary, when it is not the turn for the product to enter the relevant entrance section as a result of bar code scanning, the control logic of the twin model module may control the product in transportation not to enter the entrance section, but to go straight in operations or steps S2330, S2350.

According to various embodiments, the control logic of the twin model module may control the product to change its heading direction when all the conditions described regarding FIG. 21, FIG. 22, and FIG. 23 are satisfied. For example, as a result of bar code scanning, when it is verified that the product is a target for direction change, the number of products on an entrance section of the conveyor is less than the maximum buffer amount, and it is the turn for the product to enter the relevant entrance section, the control logic of the twin model module may change the heading direction of the product to transport the product to the entrance section.

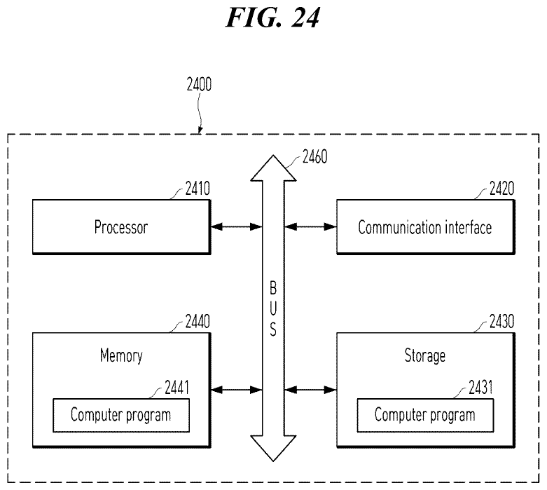

FIG. 24 is a configuration diagram of hardware of a computing device according to some embodiments of the present disclosure.

Referring to FIG. 24, each device or module forming a digital twin system (for example, a twin model module, a digital factory module, or a simulator module) may consist of a computing device 2400. For example, the computing device 2400 may include at least one processor 2410, a system bus 2460, a communication interface 2420, a memory 2440 to load a computer program 2441 to be executed by the processor 2410, and a storage 2430 to store a computer program 2431.

The processor 2410 generally controls operations of the respective components of the computing device 2400. The processor 2410 may execute computations with respect to at least one application or program to perform methods/operations according to various embodiments of the present disclosure. The memory 2440 stores various data, commands, and/or information. The memory 2440 may load at least one computer program 2441 from the storage 2430 in order to perform methods/operations according to various embodiments of the present disclosure. The bus 2460 provides communication between the components of the computing device 2400. The communication interface 2420 supports internet communication of the computing device 2400. The storage 2430 may non-provisionally store at least one computer program 2431. A computer program 2431 may include one or more instructions for implementing methods/operations according to various embodiments of the present disclosure. When the computer program 2431 is loaded in the memory 2440, the processor 2410 may execute the one or more instructions to perform methods/operations according to various embodiments of the present disclosure.

The computer program 2431 may include instructions for performing methods/operations according to various embodiments of the present disclosure.

For example, the computer program 2431 may include instructions for registering and initializing, by a simulator module, models for multiple digital factories, that are virtual representations of multiple factories; requesting, by the simulator module, the start of a simulation from a first twin model from among multiple twin models, that are virtual representations of control systems for the respective multiple factories; generating, by the first twin model, control logic for a first digital factory from among the multiple digital factories; and transferring, by the first twin model, commands generated based on the control logic to a first digital factory module.

In addition, the computer program 2431 may include instructions for receiving, by the first twin model, a request for the start of a simulation from the simulator module, wherein the first twin model is one of the multiple twin models, that are virtual representations of control systems for the respective multiple factories; generating, by the first twin model, control logic for the first digital factory from among the multiple digital factories, that are virtual representations of the multiple factories; transferring, by the first twin model, a command generated based on the control logic to the first digital factory module; processing, by the first digital factory module, an operation corresponding to the command received from the first twin model to conduct a simulation.

Hereinbefore, various embodiments of the present disclosure and benefits thereof have been described with reference to FIGS. 1-24. The benefits according to the technical spirit of the present disclosure are not limited to those mentioned above. Other benefits, not mentioned above, should be more clearly understood by those having ordinary skill in the art from the above description.

The technical spirit of the present disclosure described above may be embodied as computer-readable code on a computer-readable medium. The computer program recorded on the computer-readable recording medium may be transmitted to another computing apparatus via a network such as the Internet and installed in the other computing device, so that the computer program may be used in the other computing device.

Although operations are shown in a specific order in the drawings, it should be understood that desired results may obtained not only when the operations are performed in this specific order or a sequential order or when all the operations are performed. In certain situations, multitasking and/or parallel processing may be advantageous.

Although the embodiments of the present disclosure have been described with reference to the accompanying drawings, those having ordinary skill in the art to which the present disclosure pertains should understand that the present disclosure may be modified or altered in other specific forms without changing the technical spirit or essential features. Therefore, the embodiments described above should be understood in all respects as illustrative and not restrictive. The scope of protection of the present disclosure should be interpreted in accordance with the claims below, and all technical ideas within the equivalent scope should be construed as being included in the scope of right of the technical ideas defined by the present disclosure.

What is claimed is:

1. A system for controlling a conveyor in a virtual environment, the system comprising:
a twin model module comprising control logic and configured to virtualize a control system for conveyors installed in a factory; and
a digital factory module configured to virtualize the conveyors installed in the factory and create a virtual factory model controlled by the twin model module,
wherein a virtualized conveyor includes multiple paths formed by segmenting the conveyor based on joints, and wherein the twin model module is configured to control transportation routes of products based on the joints.

2. The system of claim 1, wherein, the twin model module is configured to:
when a product is being transported through the multiple paths included in the conveyor, verify whether a distance of the product to a preceding product is within a predetermined range; and
when the distance is within the predetermined range, control the product in transportation to stop by the control logic.

3. The system of claim 1, wherein:
the multiple paths include at least one straight path and at least one turning path; and
the twin model module is configured to set at least one of a length, an angle of gradient, or a moving speed for each straight path.

4. The system of claim 1, wherein:
the multiple paths include at least one straight path and at least one turning path; and
the twin model module is configured to set at least one of a turning section, a turning angle, or a moving speed for each turning path.

5. The system of claim 1, wherein the twin model module is configured to set transportation routes of products that are transported through the conveyor based on combination of the multiple paths.

6. The system of claim 1, wherein a direction changing unit for changing directions is disposed in each joint, and wherein the direction changing unit includes a bar code or a bar code reader.

7. The system of claim 6, wherein the twin model module is configured to, when it is verified that a product in transportation is not a target for direction change as a result of bar code scanning, control the product in transportation to go straight by the control logic.

8. The system of claim 6, wherein the twin model module is configured to, when it is verified that a number of products on an entrance section of the conveyor is equal to or higher than a predetermined number as a result of bar code scanning, control the product in transportation to go straight by the control logic.

9. The system of claim 6, wherein the twin model module is configured to, when it is verified that a product in transportation is not to enter the conveyor as a result of bar code scanning, control the product in transportation to go straight by the control logic.

10. The system of claim 6, wherein the twin model module is configured to, when it is verified that a product in transportation is a target for direction change as a result of bar code scanning, control the product in transportation to change its direction by the control logic.

11. The system of claim 1, wherein:
the twin model module is one of multiple twin model modules included in the system; and
the system further includes a simulator module to control the multiple twin model modules.

12. The system of claim 11, wherein:
the multiple twin model modules are executed on at least one graphics processing unit (GPU) server; and
the simulator module is configured to, when a first twin model module, among the multiple twin model modules, is executed, assign resources for executing the first twin model module in the at least one GPU server.

13. The system of claim 11, wherein the simulator module is configured to set up conditions of the control logic for each twin model module, among the multiple twin model modules, to control a virtual factory.

14. The system of claim 13, wherein the simulator module is configured to create webpages to set up the conditions of the control logic and sets up the conditions of the control logic using set values inputted through the webpages.

15. A method for controlling a conveyor in a virtual environment, the method comprising:
registering and initializing, by a simulator module, a model for a digital factory including a virtualized conveyor that is a virtual representation of the conveyor installed in an actual factory;
requesting, by the simulator module, start of a simulation from a twin model module that is a virtual representation of a control system for the actual factory;
generating, by the twin model module, control logic for the digital factory;
transferring, by the twin model module, a command generated based on the control logic to a digital factory module; and
processing, by the digital factory module, an operation corresponding to the command received from the twin model module to conduct a simulation,
wherein the virtualized conveyor is segmented into multiple paths based on joints, and wherein the twin model module is configured to control transportation routes of products based on the joints.

16. The method of claim 15, further comprising:
when a product is being transported through the multiple paths included in the conveyor, verifying, by the twin model module, whether a distance of the product to a preceding product is within a predetermined range; and
when the distance is within the predetermined range, controlling, by the twin model module, the product in transportation to stop by the control logic.

17. The method of claim 15, wherein:
a bar code or a bar code reader for changing directions is disposed in each joint; and
the method includes, when it is verified that a product in transportation is not a target for direction change as a result of bar code scanning, controlling, by the twin model module, the product in transportation to go straight by the control logic.

18. The method of claim 15, wherein:
a bar code or a bar code reader for changing directions is disposed in each joint; and
the method includes, when it is verified that a number of products on an entrance section of the conveyor is equal to or higher than a predetermined number as a result of bar code scanning, controlling, by the twin model module, a product in transportation to go straight by the control logic.

19. The method of claim 15, wherein:
a bar code or a bar code reader for changing directions is disposed in each joint; and
the method includes, when it is verified that a product in transportation is not to enter the conveyor as a result of bar code scanning, controlling, by the twin model module, the product in transportation to go straight by the control logic.

20. A non-transitory computer-readable recording medium storing instructions that, when executed by at least one processor, cause the at least one processor to:
register and initialize, using a simulator module, a model for a digital factory including a virtualized conveyor that is a virtual representation of a conveyor installed in an actual factory;
request, using the simulator module, start of a simulation from a twin model module that is a virtual representation of a control system for the factory;
generate, using the twin model module, control logic for the digital factory;
transfer, using the twin model module, a command generated based on the control logic to a digital factory module; and
process, using the digital factory module, an operation corresponding to the command received from the twin model module to conduct a simulation,
wherein the virtualized conveyor is segmented into multiple paths based on joints, and wherein the twin model module is configured to control transportation routes of products based on the joints.
